(19) United States
(12) Patent Application Publication
(10) Pub. No.: US 2019/0287794 A1
(43) Pub. Date: Sep. 19, 2019

(54) TEMPLATE, METHOD OF FABRICATING TEMPLATE, AND METHOD OF MANUFACTURING SEMICONDUCTOR DEVICE

(71) Applicant: TOSHIBA MEMORY CORPORATION, Tokyo (JP)

(72) Inventors: Kaori UMEZAWA, Yokohama Kanagawa (JP); Motofumi KOMORI, Yokohama Kanagawa (JP); Kazuto MATSUKI, Oota Tokyo (JP); Ryoichi SUZUKI, Yokohama Kanagawa (JP)

(21) Appl. No.: 16/102,626

(22) Filed: Aug. 13, 2018

(30) Foreign Application Priority Data
Mar. 19, 2018 (JP) 2018-051535

(51) Int. Cl. H01L 21/027; G03F 7/00; H01L 21/033; H01L 21/02

(52) U.S. Cl. CPC H01L 21/0274; H01L 21/02348; H01L 21/0337; G03F 7/0002

(57) ABSTRACT

A template includes a base, and a protruding portion on the base and having a pattern on an upper surface thereof. A side wall of the protruding portion includes impurities at a surface of the side wall and inwardly of the side wall.

This application is based upon and claims the benefit of priority from Japanese Patent Application No. 2018-051535, filed Mar. 19, 2018, the entire contents of which are incorporated herein by reference.

### FIELD

Embodiments described herein relate generally to a template, a method of fabricating a template, and a method of manufacturing a semiconductor device.

### BACKGROUND

In a nanoimprint method for forming a fine pattern in a semiconductor device, a template having a pattern region is pressed against a resist applied on a film to be processed. As a result, the pattern is transferred to the resist.

When the template is pressed against the resist, the resist protruding outside a pattern region sometimes attaches to the template. In this case, manufacturing defects may occur due to the attached resist.

### DESCRIPTION OF THE DRAWINGS

FIG. 1A is a cross section view of a template according to a first embodiment, and FIG. 1B is a plan view illustrating a second surface of a protruding portion of the template;

FIGS. 2A, 2B and 2C are plan views illustrating a side wall and a second surface of a protruding portion of the template;

FIGS. 3-4 are diagrams illustrating a forming process of the protruding portion of the template;

FIG. 5 is a diagram illustrating a masking process according to the first embodiment;

FIG. 6 is a diagram illustrating an etching process according to the first embodiment;

FIG. 7 is a diagram illustrating an ion implantation process according to the first embodiment;

FIG. 8 is a diagram illustrating a forming process of a liquid repellent region according to the first embodiment;

FIG. 9A shows a simulation result of fluorine concentration distribution during fluorine ion implantation, and FIG. 9B shows a simulation result of carbon concentration distribution during carbon ion implantation;

FIG. 10 is a diagram illustrating a modification of the ion implantation process;

FIG. 11 is a diagram illustrating a forming process of a film to be processed and a resist;

FIG. 12 is a diagram illustrating a process of pressing a template against a resist;

FIG. 13 is a diagram illustrating an ultraviolet irradiation process;

FIG. 14 is a diagram illustrating a pattern transfer process;

FIG. 15 is a diagram illustrating a forming process of a pattern region;

FIG. 16 is a diagram illustrating a masking process of the pattern region;

FIG. 17 is a diagram illustrating an ion implantation process according to a second embodiment; and

FIG. 18 is a diagram illustrating a forming process of a liquid repellent region according to the second embodiment.

### DETAILED DESCRIPTION

Embodiments provide a template having a liquid repellent region on a side wall of a protruding portion on which a pattern is formed, a method of fabricating the template, and a method of manufacturing a semiconductor device using the template.

In general, according to one embodiment, a template includes a base, and a protruding portion on the base and having a pattern on an upper surface thereof. A side wall of the protruding portion includes impurities at a surface of the side wall and inwardly of the side wall.

Embodiments of the present disclosure will now be described with reference to the accompanying drawings. The embodiments do not limit the present disclosure.

### First Embodiment

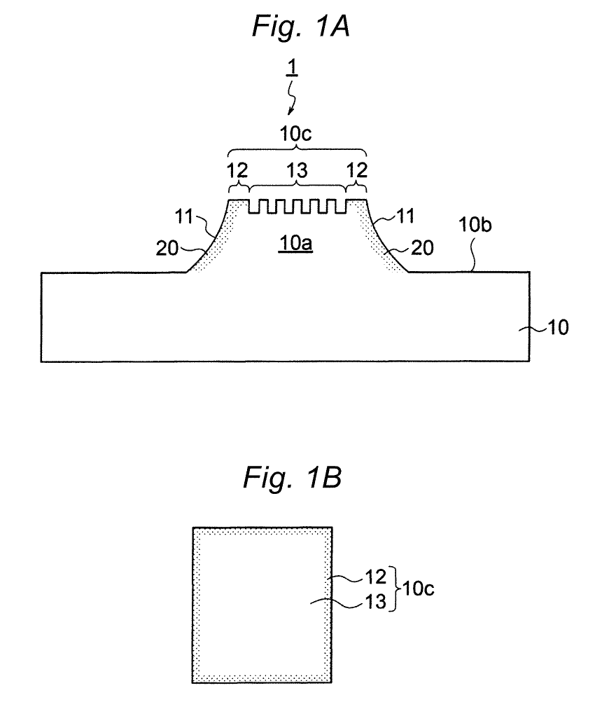

FIG. 1A is a cross section view of a template according to a first embodiment. A template 1 shown in FIG. 1A includes a base 10. The base 10 is, for example, a quartz glass substrate. The base 10 is provided with a protruding portion 10a. The protruding portion 10a is formed on a first surface 10b of the base 10, and may be formed integrally with the base 10 or separately from the base 10.

A side wall 11 of the protruding portion 10a is a liquid repellent region 20 having a higher impurity concentration than the center portion of the protruding portion 10a or the base 10. Impurities include at least one or more elements or compounds of, for example, fluorine (F), carbon (C), silicon (Si), oxygen (O) and boron fluoride (BF₂). For example, the contact angle of the liquid repellent region 20 with respect to a resist is larger than the contact angle of a region of the base 10 excluding the liquid repellent region 20 with respect to the resist.

FIG. 1B is a plan view illustrating a second surface 10c of the protruding portion 10a. A second surface 10c is also referred to as mesa portion. Here, the pattern is existing in FIG. 1B though it is not explicitly illustrated. As shown in FIG. 1B, the end portion of the second surface 10c of the protruding portion 10a also contains impurities. That is, the outer peripheral region 12 of the second surface 10c is part of the liquid repellent region 20.

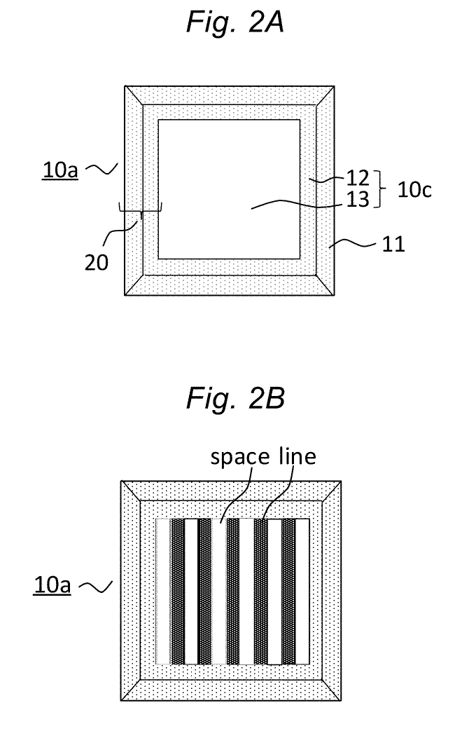

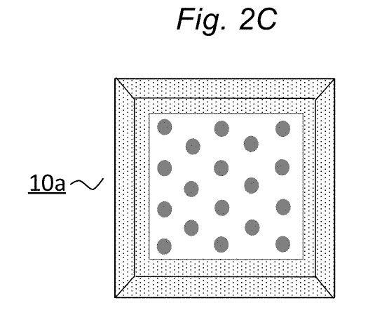

FIGS. 2A, 2B, and 2C are plan views illustrating a side wall and a second surface 10c of the protruding portion 10a. As shown, the liquid repellent region 20 is continuous from the side wall 11 to the outer peripheral region 12. In FIG. 2A, a pattern region 13 having a pattern (not explicitly illustrated) is provided on the inner side of the outer peripheral region 12. FIG. 2B is an example of line and space patterns. The line may be a convex shape or may be a concave shape (i.e. groove shape). FIG. 2C is an example of lattice-shaped dot patterns. The dot patterns may be a hole shape or may be a pillar shape. Here, in FIG. 1B, FIG. 2A, FIG. 2B, and FIG. 2C, corner portions of the side wall 11, the outer peripheral region 12, and a pattern region 13 may possibly be rounded.

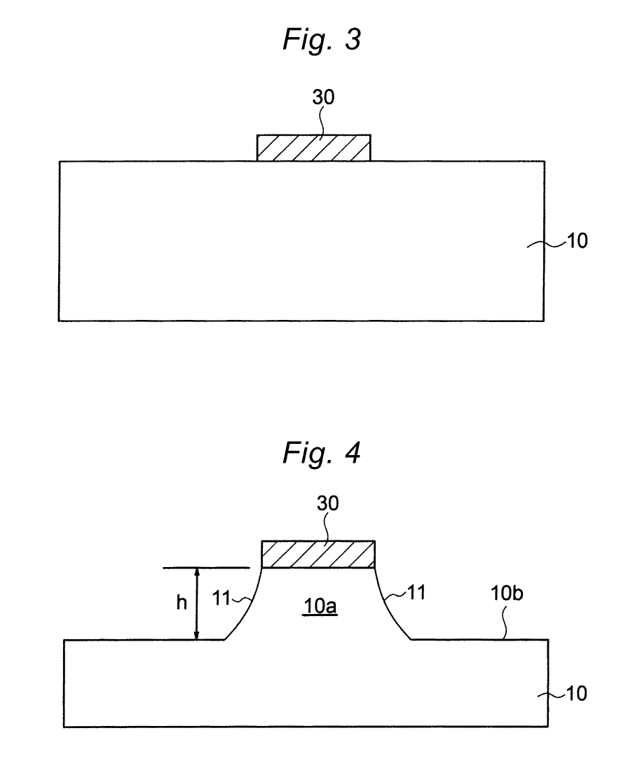

A method of fabricating the template 1 according to the embodiment will now be described with reference to FIGS. 3 to 8.

First, as shown in FIG. 3, a mask 30 is formed on the surface of the flat base 10. The mask 30 is, for example, a chromium mask, and is patterned into a desired shape.

Next, as shown in FIG. 4, a portion not masked with the mask 30 is etched using, for example, a hydrofluoric acid (HF) solution. As a result, the first surface 10b of the base 10 recedes, and the protruding portion 10a is formed. The height h of the protruding portion 10a is, for example, about 30 μm. After etching the base 10, the mask 30 is peeled off.

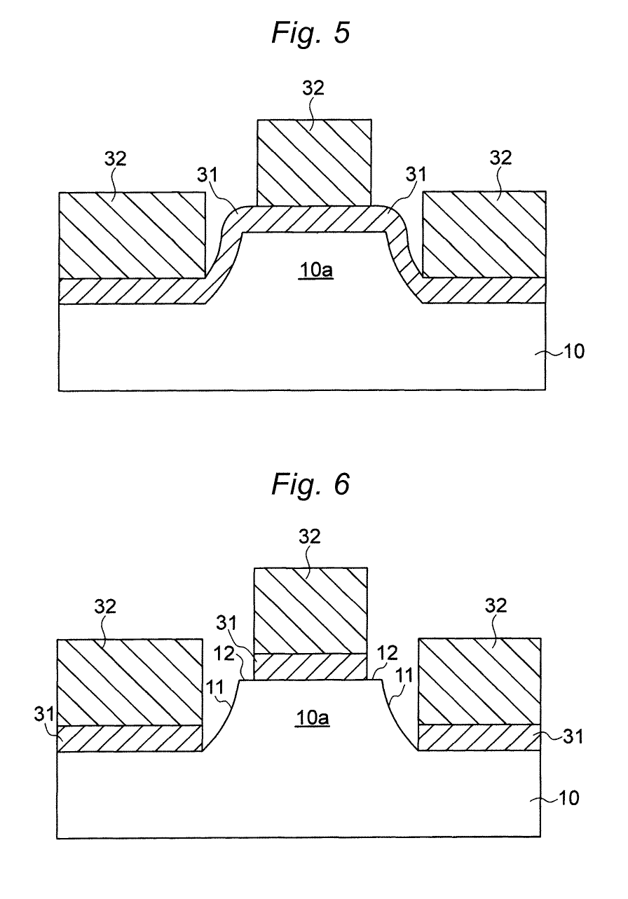

Next, as shown in FIG. 5, a mask 31 and a resist 32 are formed. The mask 31 is, for example, a chromium mask, and is formed on the first surface 10b of the base 10, and the side wall 11 and the second surface 10c of the protruding portion 10a. The resist 32 is partially formed on the mask 31. The resist 32 is, for example, an organic film.

Next, as shown in FIG. 6, the mask 31 is removed by dry etching using the resist 32 as a mask. As a result, the side wall 11 and the outer peripheral region 12 of the protruding portion 10a become exposed.

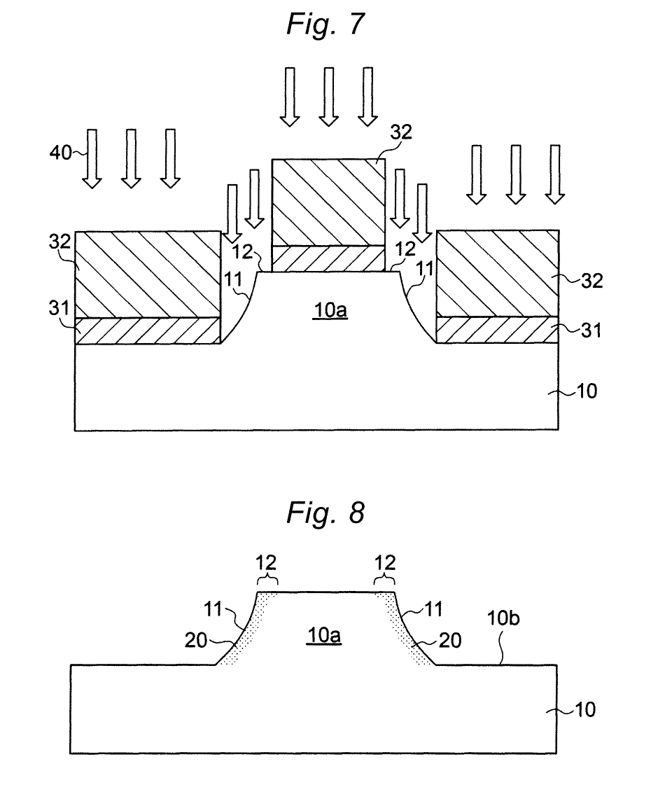

Next, as shown in FIG. 7, impurity ions 40 are implanted from, for example, above the base 10. The impurity ions 40 include ions of at least one or more elements or compounds of, for example, fluorine, carbon, silicon, oxygen and boron fluoride.

After implantation of the impurity ions 40, the mask 31 and the resist 32 are removed. Subsequently, the base 10 and the impurity implanted region are heat-treated. As a result, the impurity implanted region is modified, and the liquid repellent region 20 having higher liquid repellent performance is formed. Thereafter, as shown in FIG. 1A, a pattern is formed in the pattern region 13.

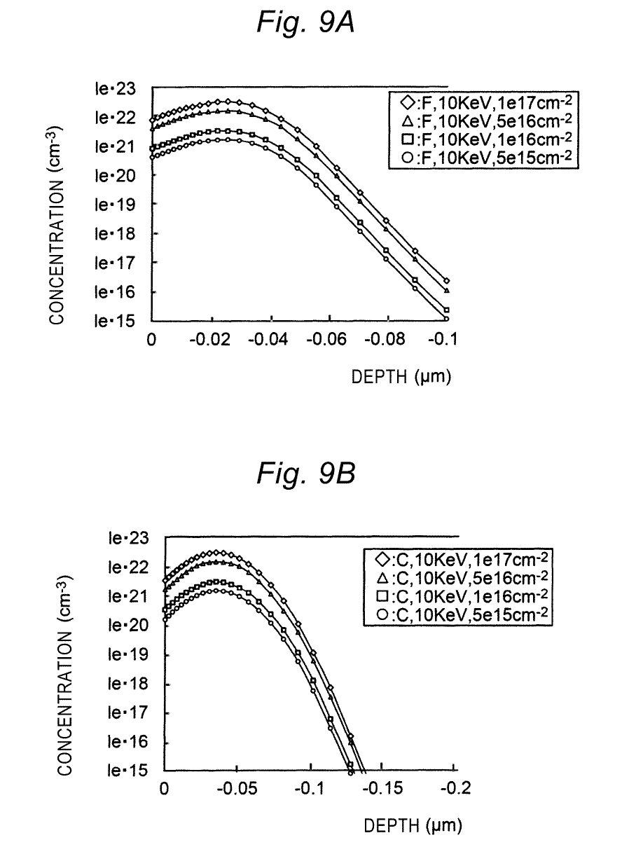

FIG. 9A shows a simulation result of the distribution of fluorine concentration in the side wall 11 when fluorine ions are implanted as the impurity ions 40. Further, FIG. 9B shows a simulation result of the distribution of fluorine concentration in the side wall 11 when carbon ions are implanted. In FIGS. 9A and 9B, the horizontal axis represents the depth from the surface of the side wall 11, and the vertical axis represents the concentration of fluorine or carbon. Regarding a simulation condition, the acceleration voltage is fixed to 10 keV, and the dose amount is set to 4 conditions of 5×10¹⁵ cm⁻², 1×10¹⁶ cm⁻², 5×10¹⁶ cm⁻², and 1×10¹⁷ cm⁻².

In the embodiment, the liquid repellent region 20 is formed by impurity ion implantation. Therefore, as shown in FIGS. 9A and 9B, the concentration of fluorine or carbon in the side wall 11 varies continuously according to the depth from the surface of the side wall 11.

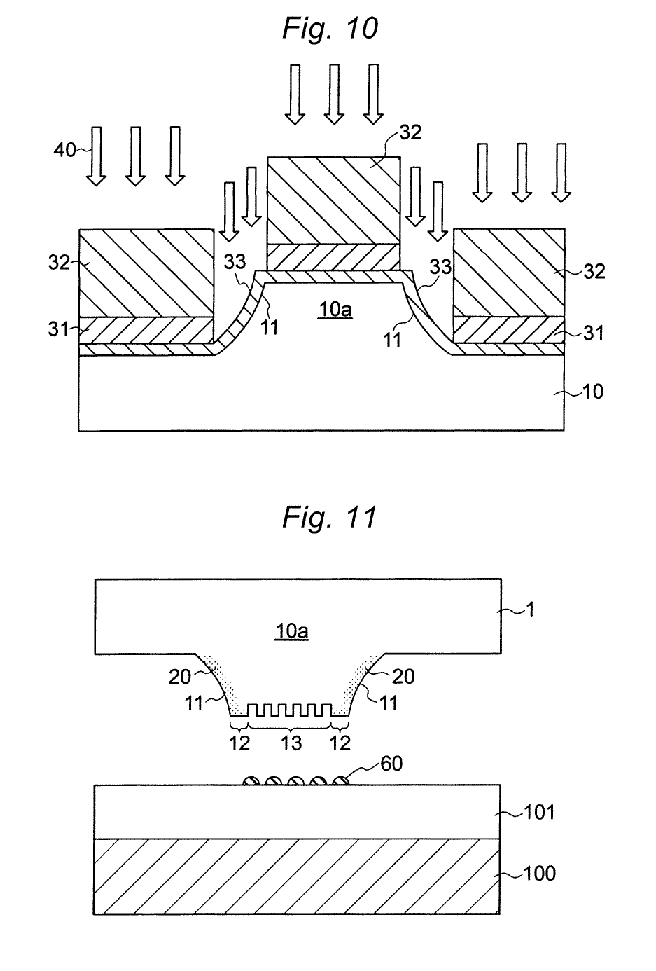

Further, according to FIGS. 9A and 9B, the maximum value of the concentration exists within the range of the depth of −0.02 μm to −0.05 μm. Therefore, as shown in FIG. 10, ions 40 may be implanted, for example, in a state where the surfaces of the impurity ion implantation portions (the side wall 11 and the outer peripheral region 12) are covered with a through film 33.

The through film 33 can be formed, for example, as an oxide film, a nitride film, an organic film or a chromium film. The thickness of the through film 33 is desirably from 0.02 μm to 0.05 μm so that the concentration of fluorine or carbon is maximized on the surfaces of the side wall 11 and the outer peripheral region 12. As a result, the liquid repellent effect can be further enhanced as will be described later. It is noted that after the ion implantation, the through film 33 is removed. In the embodiment, the condition of the ion implantation of low acceleration is used, but ion implantation may be performed under the condition of medium acceleration or high acceleration by making the through film thicker. Further, it is possible to achieve a desired concentration by ion implantation a plurality of times while changing the angle.

A method of manufacturing a semiconductor device using the above-described template 1 will now be described with reference to FIGS. 11 to 14. Here, nanoimprint processing will be described.

First, as shown in FIG. 11, a film to be processed 101 is formed on a semiconductor substrate 100. The film to be processed 101 may be a conductive film or an insulating film. Further, the film to be processed 101 may be a single layer film or stacked films. Further, the semiconductor substrate 100 may have a structure including a fine pattern in advance. A resist 60 is formed on the film to be processed 101. The resist 60 is dropped, for example, from above the film to be processed 101 into a shot region (which is a region where a pattern is formed by one time nanoimprint processing) by inkjet or the like. Alternatively, the resist 60 may be applied to the entire surface of the film to be processed 101 by spin coating or the like.

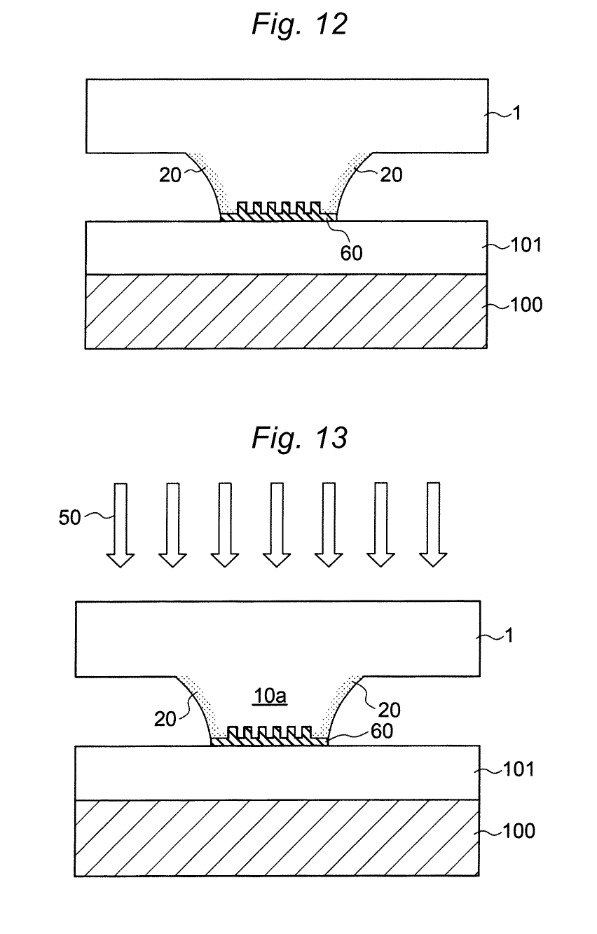

Next, as shown in FIG. 12, the second surface 10c of the protruding portion 10a of the template 1 is pressed against the resist 60. As a result, the resist 60 is filled in the pattern region 13 of the protruding portion 10a.

Next, as shown in FIG. 13, ultraviolet rays 50 are irradiated from above the template 1 in a state where the protruding portion 10a is pressed against the resist 60. As a result, the resist 60 is cured.

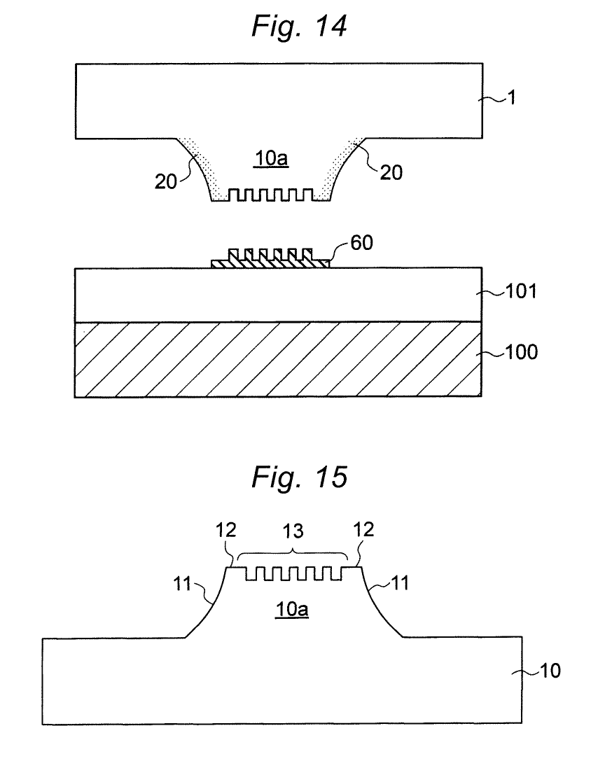

Next, as shown in FIG. 14, the template 1 is separated from the resist 60. At this time, the pattern region 13 is transferred to the resist 60. Thereafter, the film to be processed 101 is processed based on the pattern of the resist 60. As a result, a desired pattern can be formed on the film to be processed 101. This pattern can be used for patterning during general semiconductor device manufacturing, such as etching by liquid or gas, ion implantation, etc., thus, making it possible to manufacture a semiconductor device having a desired pattern.

Next, the liquid repellent effect by the template 1 of the embodiment will be described. In the process shown in FIG. 12, it is conceivable that the resist 60 protruding from the pattern region 13 attaches to the side wall 11 of the protruding portion 10a. The attached resist 60 is cured by a subsequent ultraviolet curing process and remains on the film to be processed 101 when the template 1 is retracted. When the nanoimprint processing is repeated, processing defects of the film to be processed 101 may occur due to the remaining resist.

However, in the embodiment, the liquid repellent region 20 is formed in the side wall 11 and the outer peripheral region 12 of the protruding portion 10a. The liquid repellent region 20 is a region having a high contact angle with respect to the resist. Therefore, the resist 60 protruding from the pattern region 13 stops in the outer peripheral region 12, thus, it is possible to reduce the possibility that the resist 60 attaches to the side wall 11.

According to the embodiment described above, since the liquid repellent region 20 is formed around the pattern region 13, it is possible to avoid attachment of the resist 60 to the side wall 11 of the protruding portion 10a.

Further, in the embodiment, the liquid repellent region 20 is formed by ion implantation. Therefore, as compared with the case where a liquid repellent film is formed by vapor deposition, for example, the liquid repellent region 20 is less likely to peel off the template 1, and the durability is excellent.

Further, impurities are implanted in the protruding portion 10a from the surface to a deep position by ion implantation. Therefore, even if the liquid repellent effect is deteriorated with change in time, the region with a high impurity concentration may be exposed by cleaning the template 1 and etching the surface thereof. This makes it possible to restore the liquid repellent effect.

### Second Embodiment

A second embodiment is different from the first embodiment in a method of fabricating a template. A method of fabricating a template according to the embodiment will now be described with reference to FIGS. 15 to 18. It is noted that description of processes similar to those of the first embodiment will be omitted.

First, in the same manner as in the first embodiment, a protruding portion 10a is formed on a part of the base 10 (see FIGS. 3 and 4).

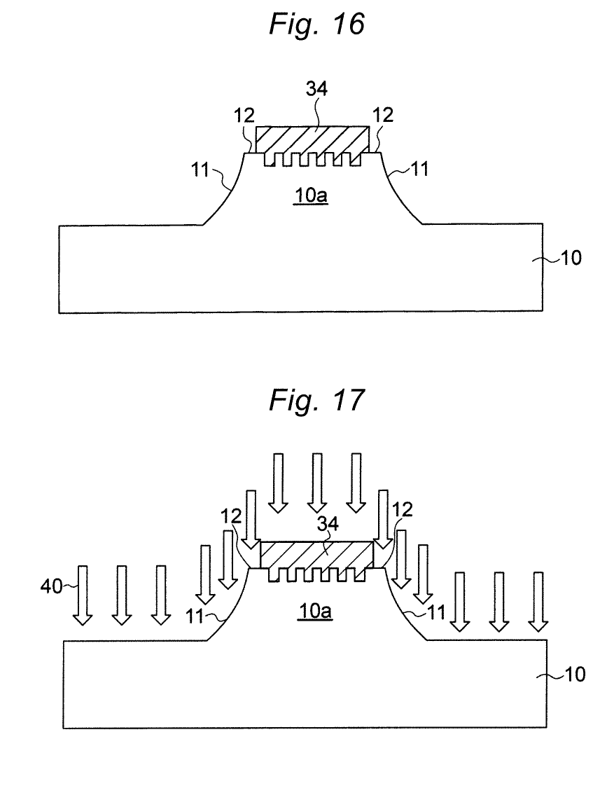

Next, as shown in FIG. 15, a pattern region 13 is formed on the upper surface of the protruding portion 10a. Next, as shown in FIG. 16, the pattern region 13 is masked with a resist 34. The resist 34 is, for example, an organic film.

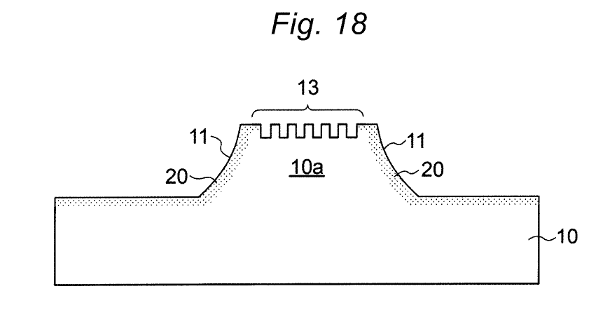

Next, as shown in FIG. 17, impurity ions 40 are implanted from above the base 10. Thereafter, the resist 34 is removed, and the base 10 and the impurity implanted region are heat-treated. As a result, as shown in FIG. 18, the liquid repellent region 20 is formed on the entire surface of the base 10 excluding the pattern region 13.

According to the embodiment described above, as in the first embodiment, since the liquid repellent region 20 is formed around the pattern region 13, it is possible to avoid attachment of the resist 60 to the side wall 11. Particularly in the embodiment, the impurity ion implantation range is wider than that in the first embodiment. Therefore, during the nanoimprint processing, the resist 60 is unlikely to attach to the template.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising:
a base, and
a protruding portion on the base and having a pattern on an upper surface thereof,
wherein a side wall of the protruding portion includes impurities at a surface of the side wall and inwardly of the side wall.

2. The template according to claim 1, wherein
the upper surface has a first region and a second region surrounding the first region, and
the impurities are also included in the second region.

3. The template according to claim 2, wherein
the pattern is formed in the first region.

4. The template according to claim 3, wherein the side wall and the second region are more liquid repelling than the first region.

5. The template according to claim 2, wherein the impurities are included continuously from the second region of the first surface to the side wall.

6. The template according to claim 1, wherein the impurities include at least one or more elements or compounds of fluorine (F), carbon (C), silicon (Si), oxygen (O) and boron fluoride (BF₂).

7. The template according to claims 1, wherein a concentration of the impurities continuously varies with respect to a depth from the surface of the side wall.

8. The template according to claims 7, wherein the concentration of the impurities is at a maximum at a predetermined depth from the side wall.

9. The template according to claims 7, wherein the concentration of the impurities is at a maximum at a surface of the side wall.

10. A method of fabricating a template, comprising:
forming a protruding portion on a part of a base;
implanting ions within at least a side wall of the protruding portion; and
heat treating the base and the protruding portion to restore damaged surfaces of ion implanted regions.

11. The method of fabricating a template according to claim 10, wherein the ions are also implanted within an outer peripheral region of an upper surface of the protruding portion.

12. The method of fabricating a template according to claim 11, wherein a pattern region is formed inside the outer peripheral region of the upper surface of the protruding portion after the heat treatment.

13. The method of fabricating a template according to claim 10, further comprising:
forming a pattern region inside an outer peripheral region of an upper surface of the protruding portion; and
masking the pattern region while implanting the ions.

14. The method of fabricating a template according to claim 10, further comprising:
prior to implanting the ions, covering the side wall with a film having a predetermined thickness, so that ions are implanted through the film; and
after implanting the ions, removing the film.

15. The method of fabricating a template according to claim 10, wherein the ions include at least one or more elements or compounds of fluorine (F), carbon (C), silicon (Si), oxygen (O) and boron fluoride (BF₂).

16. A method of manufacturing a semiconductor device, comprising:
forming a film to be processed on a semiconductor substrate;
dropping or applying a resist on the film to be processed;
pressing a surface of a protruding portion of a template, on which a pattern is formed, against the resist;
curing the resist;
separating the template from the resist after the resist is cured; and
processing the film to be processed using the resist as a mask, wherein
the protruding portion of the template is formed on a base, and a side wall of the protruding portion includes impurities at a surface of the side wall and inwardly of the side wall.

17. The method of manufacturing a semiconductor device according to claim 16, wherein the side wall is more liquid repelling than the surface of the protruding portion on which the pattern is formed.

18. The method of manufacturing a semiconductor device according to claims 16, wherein a concentration of the impurities continuously varies with respect to a depth from the surface of the side wall.

19. The method of manufacturing a semiconductor device according to claims 18, wherein the concentration of the impurities is at a maximum at a predetermined depth from the side wall.

20. The method of manufacturing a semiconductor device according to claims 18, wherein the concentration of the impurities is at a maximum at a surface of the side wall.
